(19) United States
(12) Patent Application Publication
(10) Pub. No.: US 2026/0026285 A1
(43) Pub. Date: Jan. 22, 2026

(54) SUBSTRATE PROCESSING APPARATUS AND SUBSTRATE PROCESSING METHOD

(71) Applicant: Tokyo Electron Limited, Tokyo (JP)

(72) Inventors: Munehisa KODAMA, Kikuchi-gun, Kumamoto (JP); Takayoshi WAKAMATSU, Kikuchi-gun, Kumamoto (JP)

(21) Appl. No.: 19/111,807

(22) PCT Filed: Aug. 31, 2023
(86) PCT No.: PCT/JP2023/031783

§ 371 Date: Mar. 14, 2025

(30) Foreign Application Priority Data
Sep. 16, 2022 (JP) 2022-147678

(51) Int. Cl. H01L 21/67; B24B 7/04; B24B 7/22; H01L 21/304; H01L 21/687

(52) U.S. Cl. CPC H01L 21/67051; B24B 7/04; H01L 21/304; H01L 21/68764; B24B 7/228

(57) ABSTRACT

A substrate processing apparatus includes a substrate holder for holding a substrate; a driving mechanism for driving a tool for processing the substrate held by the substrate holder; a housing that accommodates the substrate holder and the tool; and a sprayer for spraying a liquid to an inside of the housing in a form of mist.

### TECHNICAL FIELD

The various aspects and embodiments described herein pertain generally to a substrate processing apparatus and a substrate processing method.

### BACKGROUND

A plane processing apparatus described in Patent Document 1 has a housing that accommodates a chuck and an index table, and grinds a substrate with a grindstone while supplying a grinding liquid to the substrate therein.

### PRIOR ART DOCUMENT

Patent Document 1: Japanese Patent Laid-open Publication No. 2010-124006

### DISCLOSURE OF THE INVENTION

### Problems to be Solved by the Invention

Exemplary embodiments provide a technique capable of suppressing adhesion of contaminants inside a housing.

### Means for Solving the Problems

In an exemplary embodiment, a substrate processing apparatus includes a substrate holder configured to hold a substrate; a driving mechanism configured to drive a tool configured to process the substrate held by the substrate holder; a housing that accommodates the substrate holder and the tool; and a sprayer configured to spray a liquid to an inside of the housing in a form of mist.

### Effect of the Invention

According to the exemplary embodiments, it is possible to suppress the adhesion of the contaminants inside the housing.

### BRIEF DESCRIPTION OF THE DRAWINGS

FIG. 1 is a plan view illustrating a substrate processing apparatus according to an exemplary embodiment.

FIG. 2 is a cross sectional view illustrating an example of a driving mechanism.

FIG. 3 is an enlarged cross sectional view of a part of FIG. 2.

FIG. 4 is a plan view illustrating an example of a sprayer.

### DETAILED DESCRIPTION

Hereinafter, exemplary embodiments of the present disclosure will be described with reference to the accompanying drawings. In the various drawings, same or corresponding parts will be assigned same reference numerals, and redundant descriptions thereof will be omitted. In the present specification, the X-axis, Y-axis and Z-axis directions are perpendicular to each other. The X-axis direction and the Y-axis direction are horizontal directions, and the Z-axis direction is a vertical direction.

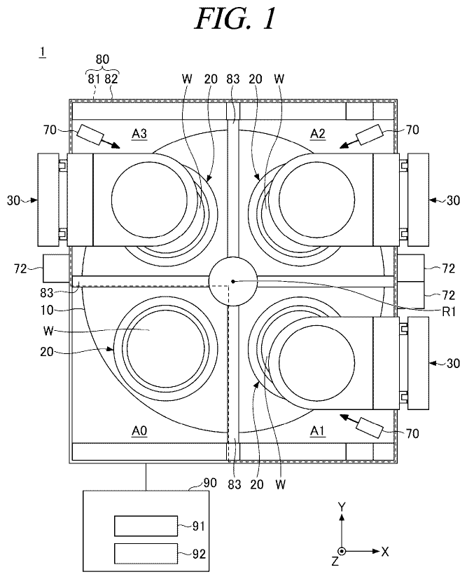

Referring to FIG. 1, a substrate processing apparatus 1 according to an exemplary embodiment will be explained. The substrate processing apparatus 1 is configured to grind, for example, a substrate W. The grinding includes polishing. The substrate processing apparatus 1 is equipped with, by way of example, a rotary table 10, four chucks 20 each configured to hold the substrate W, three driving mechanisms 30 each configured to drive a tool D for processing the substrate W, a housing 80 accommodating chucks 20 and the tools D, and a control device 90.

The rotary table 10 holds the four chucks 20 at an equi-distance around a rotation center line R1, and rotates around the rotation center line R1. Each of the four chucks 20 rotates together with the rotary table 10 and moves to a carry-in/out position A0, a first processing position A1, a second processing position A2, and a third processing position A3, and then back to the carry-in/out position A0 in this order.

The carry-in/out position A0 serves as both a carry-in position where carrying-in of the substrate W is performed and a carry-out position where carrying-out of the substrate W is performed. Though the carry-in position and the carry-out position are identical in the present exemplary embodiment, they may be different.

The first processing position A1 is a position where a primary processing (for example, primary grinding) is performed. The second processing position A2 is a position where a secondary processing (for example, secondary grinding) is performed. The third processing position A3 is a position where a tertiary processing (for example, tertiary grinding) is performed.

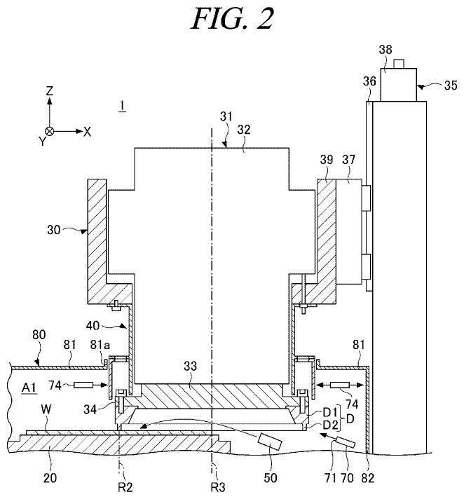

The four chucks 20 are mounted to the rotary table 10 so as to be rotatable around their own rotation center lines R2 (see FIG. 2). At the first processing position A1, the second processing position A2, and the third processing position A3, the chucks 20 rotate around their own rotation center lines R2, respectively.

One of the driving mechanisms 30 performs the primary processing of the substrate W at the first processing position A1. Another driving mechanism 30 performs the secondary processing of the substrate W at the second processing position A2. The other driving mechanism 30 performs the tertiary processing of the substrate W at the third processing position A3.

The housing 80 suppresses a processing waste and a processing liquid from being scattered to the outside. The processing waste is powder or fragments generated when processing the substrate W. The powder includes powder cut out from the substrate W and abrasive grains separated from the tool D. The processing liquid is, for example, pure water such as deionized water (DIW). The processing liquid is introduced between the tool D and the substrate W to reduce frictional resistance and frictional heat. The processing liquid is supplied by a nozzle 50 (see FIG. 2).

The housing 80 has a top panel 81 located above the chuck 20, and a side panel 82 located on the lateral side of the chuck 20. The top panel 81 is horizontal, and the side panel 82 is vertical. The top panel 81 is located above the side panel 82. The top panel 81 is provided with a passage opening 81a (see FIG. 2) through which the tool D and the like passes.

As indicated by a dashed line in FIG. 1, the top panel 81 covers, for example, spaces above the first processing position A1, the second processing position A2, and the third processing position A3, while allowing a space above the carry-in/out position A0 to be opened. By way of example, the top panel 81 has a rectangular shape with its one corner cut out into an L-shape when viewed from above.

The inside of the housing 80 is divided into multiple rooms by partition walls 83. The partition walls 83 are fixed to a bottom surface of the top panel 81. The partition walls 83 are arranged in, for example, a cross shape. The partition walls 83 separate, for example, the carry-in/out position A0, the first processing position A1, the second processing position A2, and the third processing position A3.

The control device 90 is, for example, a computer, and includes an operation unit 91 such as a central processing unit (CPU) and a storage 92 such as a memory. The storage 92 stores therein a program that controls various processes performed in the substrate processing apparatus 1. The control device 90 controls an operation of the substrate processing apparatus 1 by causing the operation unit 91 to execute the program stored in the storage 92.

Though the substrate processing apparatus 1 grinds one surface of the substrate W in the present exemplary embodiment, it may grind both surfaces of the substrate W.

The substrate processing apparatus 1 is not limited to the grinding apparatus. The substrate processing apparatus 1 may be a cutting apparatus or the like. When the substrate processing apparatus 1 is a grinding apparatus, a grindstone or the like is used as the tool D. When the substrate processing apparatus 1 is a cutting apparatus, an end mill or the like is used as the tool D.

Now, referring to FIG. 2, an example of the driving mechanism 30 will be explained. The driving mechanism 30 is configured to rotate the tool D and move the tool D up and down. The driving mechanism 30 includes an operating device 31 to which the tool D is mounted. The tool D is pressed against the substrate W to process the substrate W. The tool D includes, by way of example, a disk-shaped grinding wheel D1, and a plurality of grindstones D2 arranged in a ring shape on a bottom surface of the grinding wheel D1.

The operating device 31 includes a motor 32, a vertical spindle shaft 33 configured to be rotated by the motor 32, and a flange 34 provided at a lower end of the spindle shaft 33. The flange 34 is horizontally arranged, and the tool D is mounted to its bottom surface. The motor 32 rotates the spindle shaft 33, thus allowing the tool D attached to the flange 34 to be rotated. A rotation center line R3 of the tool D is a rotation center line of the spindle shaft 33.

The driving mechanism 30 further includes an elevating device 35 configured to move the operating device 31 up and down. The elevating device 35 has, by way of example, a vertical Z-axis guide 36, a Z-axis slider 37 configured to be moved along the Z-axis guide 36, and a Z-axis motor 38 configured to move the Z-axis slider 37. The motor 32 is fixed to the Z-axis slider 37 with a motor holder 39 therebetween.

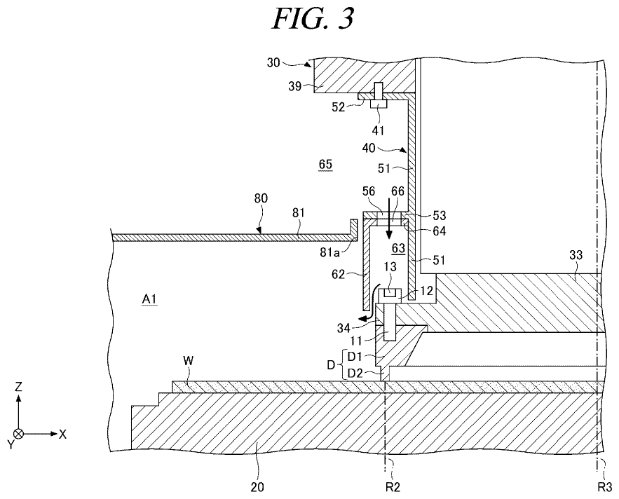

Now, mainly referring to FIG. 3, an example of a spindle cover 40 will be explained. The driving mechanism 30 is equipped with the spindle cover 40 that surrounds the spindle shaft 33. The spindle cover 40 suppresses the processing waste and the processing liquid from adhering to the spindle shaft 33 and a top surface of the flange 34.

The spindle cover 40 is fastened to the motor holder 39 by a bolt 41 or the like, and is moved up and down together with the motor 32. The spindle cover 40 has a first cylindrical member 51, an upper flange 52 provided at an upper end of the first cylindrical member 51, and an intermediate flange 53 provided between the upper end and a lower end of the first cylindrical member 51. The upper flange 52 is fastened to the motor holder 39 by the bolt 41 or the like. The upper flange 52 and the intermediate flange 53 are formed as one body with the first cylindrical member 51.

The spindle cover 40 has a second cylindrical member 62 that surrounds the first cylindrical member 51, and a ring-shaped top plate 64 that closes from above an internal space 63 formed between the first cylindrical member 51 and the second cylindrical member 62. The top plate 64 is formed as one body with the second cylindrical member 62, and is detachably connected to a bottom surface of the intermediate flange 53 by a bolt or the like. The intermediate flange 53 may be omitted, and the top plate 64 may be formed as one body with the first cylindrical member 51. The top plate 64 is provided between the upper end and the lower end of the first cylindrical member 51.

The outer diameter of the first cylindrical member 51 is smaller than the outer diameter of the flange 34. The lower end of the first cylindrical member 51 is disposed above the top surface of the flange 34 so as not to be in contact with the top surface of the flange 34.

The second cylindrical member 62 is disposed outside the first cylindrical member 51, surrounding the flange 34. The inner diameter of the second cylindrical member 62 is larger than the outer diameter of the flange 34. The second cylindrical member 62 is extended to below the top surface of the flange 34. The second cylindrical member 62 suppresses the processing waste from adhering to the top surface of the flange 34.

A head 12 of a bolt 11 is positioned on the top surface of the flange 34. The head 12 of the bolt 11 is disposed in the internal space 63. The head 12 of the bolt 11 protrudes from the top surface of the flange 34. Here, a recess for receiving the head 12 of the bolt 11 may be provided on the top surface of the flange 34.

A worker attaches or detaches the tool D by tightening or loosening the bolt 11. The head 12 of the bolt 11 is provided with a hole for work, for example, a hexagonal hole 13. The worker inserts a tip of a hexagonal wrench into the hexagonal hole 13 and turns the head 12 of the bolt 11 to tighten or loosen the bolt 11.

The spindle cover 40 suppresses the processing waste from adhering to the top surface of the flange 34. Thus, the worker may be suppressed from getting dirty when attaching or detaching the tool D. Also, the processing waste can be suppressed from being accumulated in the hexagonal hole 13 of the bolt 11, thus suppressing the hexagonal hole 13 from being clogged with the processing waste.

The present inventors have examined the cause of processing waste entering the internal space 63 of the spindle cover 40 through airflow simulation or the like. When the motor 32 rotates the spindle shaft 33, the flange 34 is rotated. It is found out that a rotating airflow is generated so as to be dragged by the rotation of the flange 34 or the head 12 of the bolt 11, resulting in generation of a negative pressure in a part of the internal space 63. It is also found that if an obstacle not shown is present in the internal space 63, disturbance of the rotating airflow increases, resulting in an increase of the negative pressure generated in the internal space 63.

In the present exemplary embodiment, an intake 66 is provided to take in a gas (for example, air) into the internal space 63 from an external space 65 of the spindle cover 40. The intake 66 is provided in the top plate 64 or in an upper portion of the second cylindrical member 62 (in the top plate 64 in FIG. 3). The intake 66 takes in the gas from the external space 65 into the internal space 63 due to a pressure difference between the external space 65 and the internal space 63.

Even if the rotating airflow is disturbed in the internal space 63 of the spindle cover 40 so the negative pressure is generated in a part of the internal space 63, a downward or obliquely downward airflow can be formed at a lower end of the internal space 63 by taking in the gas into the internal space 63 through the intake 66. Therefore, the processing waste can be suppressed from reaching the internal space 63. In addition, since a downflow can be formed near the passage opening 81a of the top panel 81, a liquid in the form of mist to be described later can be suppressed from leaking through the passage opening 81a.

The intake 66 takes in the gas into the internal space 63 from the external space 65 above the top panel 81 of the housing 80. A clean gas can be introduced into the internal space 63. In order to take in as clean a gas as possible, it is desirable that the intake 66 is positioned as high as possible. Desirably, the intake 66 is provided in the top plate 64.

The intake 66 is plural in number, and the plurality of intakes 66 are arranged at an interval therebetween in, for example, a circumferential direction of the top plate 64. The intakes 66 may be arranged at an unequal pitch, but it is desirable that they are arranged at an equal pitch. By providing the plurality of intakes 66 at the equal pitch, the gas can be evenly introduced into the internal space 63.

The intermediate flange 53 is disposed on the top plate 64 in which the intakes 66 are provided. The intermediate flange 53 is provided with communication holes 56 at its positions overlapping the intakes 66. The gas is introduced from the external space 65 into the internal space 63 through the communication holes 56 and the intakes 66. The intermediate flange 53 may have a non-illustrated notch formed to avoid the intakes 66.

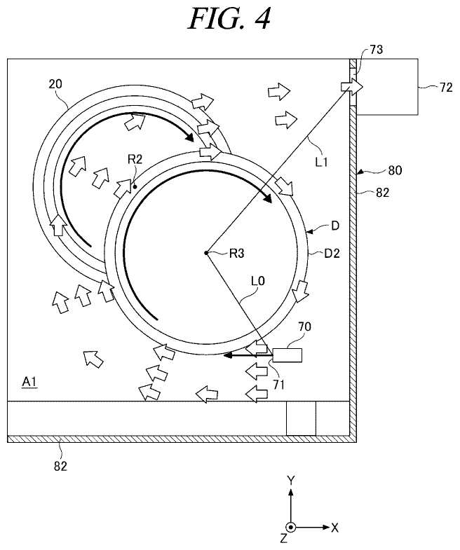

Now, an example of a sprayer 70 will be explained, mainly with reference to FIG. 4. The substrate processing apparatus 1 is equipped with the sprayer 70 configured to spray a liquid into the housing 80 in the form of mist. The sprayer 70 can suppress the inside of the housing 80 from drying out, so that adhesion of contaminants such as processing waste can be suppressed. In addition, by spraying the liquid in the form of the mist, the amount of the liquid used can be reduced. Although the liquid to be sprayed is not particularly limited, it is desirable to use the same liquid as the processing liquid (for example, DIW).

The sprayer 70 desirably includes a two-fluid nozzle. The two-fluid nozzle atomizes the liquid by using a gas pressure, and sprays the automized liquid. By atomizing the liquid, the consumption amount of the liquid can be further reduced. In addition, by atomizing the liquid, liquid droplets can be light-weighted, so that a fall of the liquid droplets in the gas can be suppressed, and the liquid droplets can be evenly supplied throughout the inside of the housing 80.

The sprayer 70 is provided at each of the first processing position A1, the second processing position A2, and the third processing position A3 (see FIG. 1), for example. With this configuration, the adhesion of contaminants such as the processing waste can be suppressed at each of the first processing position A1, the second processing position A2, and the third processing position A3. The sprayer 70 is not provided at the carry-in/out position A0 that is not covered by the top panel 81.

The sprayer 70 sprays the liquid in the form of the mist into the housing 80 between a time when the substrate processing apparatus 1 is powered on and a time when a processing of the substrate W is begun, or between a time when the processing of one substrate W is ended and a time when a processing of a next substrate W is begun, for example. The liquid can be sufficiently applied to the tool D before the processing of the substrate W is started, so that discrepancy in processing quality between the substrates W can be reduced.

During the processing of the substrate W, the processing liquid is dispersed inside the housing 80, so the inside of the housing 80 is wet. Thus, the sprayer 70 does not spray the liquid during the processing of the substrate W. However, the sprayer 70 may spray the liquid during the processing of the substrate W.

As shown in FIG. 4, it is desirable that the tool D is rotated when the sprayer 70 sprays the liquid. A rotating airflow is generated so as to be dragged by the rotation of the tool D. The rotating airflow allows the mist of the liquid to be diffused throughout the inside of the housing 80 in a short time. The spraying of the liquid and the rotation of the tool D do not have to be performed simultaneously, and may be performed alternately, for example. If a spray line of the sprayer 70 is deviated from the rotation center line R3 of the tool D when viewed from vertically above, the tool D may be rotated as a result of the liquid colliding with the tool D.

It is desirable that the chuck 20 is rotated when the sprayer 70 sprays the liquid. A rotating airflow is generated so as to be dragged by the rotation of the chuck 20. The rotating airflow allows the mist of liquid to be diffused throughout the inside of the housing 80 in a short time. The spraying of the liquid and the rotation of the chuck 20 do not need to be performed simultaneously, and may be performed alternately, for example.

When viewed from vertically above, it is desirable that the rotation direction of the tool D and the rotation direction of the chuck 20 are the same (clockwise in FIG. 4). This may suppress collision between the rotating airflow caused by the rotation of the tool D and the rotating airflow caused by the rotation of the chuck 20. Therefore, the disturbance of the airflow can be suppressed, so that the mist of the liquid can be evenly diffused throughout the inside of the housing 80.

When viewed from vertically above, the tool D is rotated in a preset direction, and the sprayer 70 sprays the liquid in the form of the mist to a downstream side in the rotation direction of the tool D with respect to a straight line LO connecting the rotation center line R3 of the tool D and an injection opening 71 of the sprayer 70. The liquid can be sprayed in the form of the mist without going against the rotating airflow caused by the rotation of the tool D.

When viewed from vertically above, the sprayer 70 is provided outside the chuck 20 and the tool D, and sprays the liquid toward the tool D in the form of the mist. By directing the spray line of the sprayer 70 toward the tool D, the liquid can be easily applied to the tool D. In particular, if the liquid is sprayed to the tool D while the tool D is being rotated, it is possible to allow the liquid to be applied to the tool D in the entire circumferential direction thereof. When viewed from vertically above, it is desirable that the sprayer 70 sprays the liquid in the form of the mist in a tangent direction of the outer circumference of the tool D.

It is desirable that the sprayer 70 sprays the liquid toward the tool D in the form of the mist from an obliquely below the tool D (see FIG. 2). A large area of the tool D can be covered with the liquid in the form of the mist. It may also be possible that the sprayer 70 sprays the liquid toward the tool D in the form of the mist from directly below the tool D.

The tool D includes, by way of example, the grindstone D2. The grindstone D2 has, for example, abrasive grains, and a vitrified bond that bonds the abrasive grains. The vitrified bond is easily deteriorated by the liquid. If the liquid is sprayed in the form of the mist, the amount of the liquid used can be reduced, so that the deterioration of the vitrified bond can be suppressed. The abrasive grains may be diamond abrasive grains though not particularly limited.

The substrate processing apparatus 1 is equipped with an exhaust device 72 that exhausts a gas inside the housing 80 to the outside of the housing 80. The inside of the housing 80 can be maintained at a negative pressure with respect to the outside of the housing 80, so that leakage of the processing waste and the processing liquid may by suppressed.

The exhaust device 72 is provided at each of the first processing position A1, the second processing position A2, and the third processing position A3 (see FIG. 1), for example. With this configuration, leakage of the processing waste and the processing liquid at each of the first processing position A1, the second processing position A2, and the third processing position A3 can be suppressed. The exhaust device 72 is not provided at the carry-in/out position A0 that is not covered by the top panel 81.

When viewed from vertically above, the tool D is rotated in a preset direction, and the gas is exhausted to the exhaust device 72 from an upstream side in the rotation direction of the tool D with respect to a straight line L1 connecting the rotation center line R3 of the tool D and an exhaust opening 73 of the exhaust device 72. The gas can be exhausted without resisting the rotating airflow caused by the rotation of the tool D.

Now, an example of a cleaning liquid nozzle 74 will be described with reference to FIG. 2. The cleaning liquid nozzle 74 discharges a cleaning liquid toward the spindle cover 40, the housing 80, or the tool D. According to the present exemplary embodiment, since adhesion of contaminants is suppressed by the sprayer 70, the contaminants can be efficiently washed away by the cleaning liquid nozzle 74.

The cleaning liquid nozzle 74 may be fixed, or may be rotated like a sprinkler. In the latter case, it is possible to wash away all contaminants from the spindle cover 40, the housing 80, and the tool D with one cleaning liquid nozzle 74.

The cleaning liquid nozzle 74 is provided at each of the first processing position A1, the second processing position A2, and the third processing position A3, for example. With this configuration, contaminants at each of the first processing position A1, the second processing position A2, and the third processing position A3 can be washed away. The cleaning liquid nozzle 74 is not provided at the carry-in/out position A0 that is not covered by the top panel 81.

The cleaning liquid nozzle 74 discharges the cleaning liquid between a time when a processing of one substrate W is ended and a time when a processing of another substrate W is begun. After the processing of the substrate W, contaminants that have adhered to the substrate W during the processing of the substrate W can be washed away.

Further, during the processing of the substrate W, supplying the cleaning liquid is of no use as the processing waste scatters inside the housing 80. Thus, the cleaning liquid nozzle 74 does not discharge the cleaning liquid. However, the cleaning liquid nozzle 74 may discharge the cleaning liquid during the processing of the substrate W.

So far, the exemplary embodiment of the substrate processing apparatus and the substrate processing method according to the present disclosure have been described. However, the present disclosure is not limited to the above-described exemplary embodiment or the like. Various changes, corrections, replacements, addition, deletion and combinations may be made within the scope of the claims, and all of these are included in the scope of the inventive concept of the present disclosure.

This application claims priority to Japanese Patent Application No. 2022-147678, field on Sep. 16, 2022, which application is hereby incorporated by reference in their entirety.

### EXPLANATION OF CODES

1: Substrate processing apparatus
20: Chuck (Substrate holder)
70: Sprayer
80: Housing
D: Tool
W: Substrate

1. A substrate processing apparatus, comprising:
a substrate holder configured to hold a substrate;
a driving mechanism configured to drive a tool configured to process the substrate held by the substrate holder;
a housing that accommodates the substrate holder and the tool;
a nozzle configured to supply a processing liquid; and
a sprayer configured to spray a liquid to an inside of the housing in a form of mist,
wherein when viewed from vertically above, the sprayer sprays the liquid in the form of the mist toward the tool in a tangent direction of an outer circumference of the tool.

2. The substrate processing apparatus of claim 1,
wherein the sprayer sprays the liquid in the form of the mist toward the tool from obliquely below the tool.

3. The substrate processing apparatus of claim 1,
wherein when viewed from vertically above, the tool is rotated in a preset direction, and the sprayer sprays the liquid in the form of the mist to a downstream side in a rotation direction of the tool with respect to a straight line connecting a rotation center line of the tool and an injection opening of the sprayer.

4. The substrate processing apparatus of claim 1,
wherein when viewed from vertically above, the tool and the substrate holder are rotated in a same preset direction, and the sprayer sprays the liquid in the form of the mist to a downstream side in a rotation direction of the tool with respect to a straight line connecting a rotation center line of the tool and an injection opening of the sprayer.

5. The substrate processing apparatus of claim 1,
wherein the driving mechanism comprises a motor, a vertical spindle shaft configured to be rotated by the motor, and a spindle cover surrounding the spindle shaft,
the housing has a top panel provided with a passage opening through which the tool passes,
the spindle cover has a first cylindrical member surrounding the spindle shaft, a second cylindrical member surrounding the first cylindrical member, and a ring-shaped top plate closing from above an internal space formed between the first cylindrical member and the second cylindrical member, and
the spindle cover is provided with an intake through which a gas is introduced into the internal space from an external space above the top panel.

6. The substrate processing apparatus of claim 1,
wherein the driving mechanism comprises a motor, a vertical spindle shaft configured to be rotated by the motor, and a spindle cover surrounding the spindle shaft, and
the substrate processing apparatus further comprises a cleaning liquid nozzle disposed in the housing and configured to discharge a cleaning liquid toward the spindle cover, the housing or the tool.

7. A substrate processing method, comprising:
processing a substrate by using a substrate processing apparatus as claimed in claim 1.

8. The substrate processing method of claim 7, further comprising:
spraying, by the sprayer, the liquid in the form of the mist to the inside of the housing between a time when a power is turned on and a time when the processing of the substrate is begun, or between a time when the processing of the substrate is ended and a time when the processing of another substrate is begun.
